(19) United States
(12) Patent Application Publication
(10) Pub. No.: US 2010/0035186 A1
(43) Pub. Date: Feb. 11, 2010

(54) MANUFACTURING A GRAPHENE DEVICE AND A GRAPHENE NANOSTRUCTURE SOLUTION

(75) Inventors: Seunghun Hong, Seoul (KR); Juntae Koh, Gyeonggi-Do (KR)

Correspondence Address: KNOBBE MARTENS OLSON & BEAR LLP, 2040 MAIN STREET, FOURTEENTH FLOOR, IRVINE, CA, 92614, US

(73) Assignee: Seoul National University Research & Development Business Foundation (SNU R&DB FOUNDATION), Seoul (KR)

(21) Appl. No.: 12/210,991

(22) Filed: Sep. 15, 2008

(30) Foreign Application Priority Data
Aug. 5, 2008 (KR) 10-2008-0076584

(51) Int. Cl. G03F 7/20; H01B 1/04; H01B 1/24; H01B 1/22

(52) U.S. Cl. 430/311; 252/502; 252/506; 252/510; 252/511

(57) ABSTRACT

Techniques for manufacturing a graphene structure solution and a graphene device are provided. A uniform graphene nanostructure solution is produced by applying anisotropic etching on a multi-layered graphene using an oxide nanowire as a mask. A graphene device is manufactured by dipping a substrate with a pattern of a molecule layer in a graphene nanostructure solution so that graphenes are aligned on the substrate with the pattern.

### TECHNICAL FIELD

The described technology relates generally to manufacturing a graphene structure solution and a graphene device.

### BACKGROUND

Graphene shows stable characteristics and high electric mobility, and has accumulated considerable interest as a material for use in next generation semiconductor devices. However, in order to show semiconductor characteristics, the graphene is typically required to be formed as a channel having a nanoscale line width. This is because the graphene basically has a metallic characteristic.

Graphene nanostructures are typically synthesized in a form of a solution or powder. Therefore, in order to manufacture a device using a graphene nanostructure, a process of aligning a graphene nanostructure on a solid surface with a desired directivity is required.

Recently, in order to commercialize a device utilizing a graphene nanostructure, techniques for selectively adhering graphene nanostructures on a substrate at desired positions have been widely studied. Among them, a technique in which a solution having graphenes dispersed therein is spread on a silicon substrate so that graphenes may be adhered on the substrate is being studied.

However, when a nanoscale graphene device is manufactured using a graphene-dispersed solution according to conventional schemes, including the aforementioned schemes, it is difficult to fabricate devices having uniformly good characteristics since the nanostructure graphenes dispersed in the solution are not uniform in their widths. In addition, a technique that positions graphenes at desired positions for mass production has not yet been developed.

### SUMMARY

Techniques for manufacturing a graphene device and a graphene nanostructure solution are provided. In one embodiment, a method of manufacturing a graphene nanostructure solution comprises: forming a target nanostructure on a multi-layered graphene; forming a multi-layered graphene nanostructure by performing anisotropic etching using the target nanostructure as a mask; and forming a solution having graphene nanostructures dispersed therein by dispersing the multi-layered graphene nanostructure in a dispersion solvent.

In one embodiment, a method of manufacturing a graphene nano device comprises: forming a molecule layer pattern having a hydrophobic molecule layer in a first region on a substrate; and aligning a graphene nanostructure in a second region of the substrate where the hydrophobic molecule layer is not formed.

In another embodiment, a method of manufacturing a graphene nano device comprises: forming a target nanostructure on a multi-layered graphene; forming a multi-layered graphene nanostructure by performing anisotropic etching using the target nanostructure as a mask; forming a solution having graphene nanostructures dispersed therein by dispersing the multi-layered graphene nanostructure in a dispersion solvent; forming a molecule layer pattern having a hydrophobic molecule layer in a first region on a substrate; and aligning a graphene nanostructure in a second region of the substrate where the hydrophobic molecule layer is not formed, by dipping the substrate with the molecule layer pattern in a solution having graphene nanostructures dispersed therein.

The Summary is provided to introduce a selection of concepts in a simplified form that are further described below in the Detailed Description. The Summary is not intended to identify key features or essential features of the claimed subject matter, nor is it intended to be used as an aid in determining the scope of the claimed subject matter.

### BRIEF DESCRIPTION OF THE DRAWINGS

FIGS. 1A-1F illustrate a process of a method of manufacturing a solution including graphene nanostructures dispersed therein according to an example embodiment.

FIG. 2 is a flowchart that shows a method of manufacturing a solution including graphene nanostructure dispersed therein according to an example embodiment.

FIGS. 3A-3D illustrate a process of a method of manufacturing a graphene device according to an example embodiment.

FIG. 4 is a flowchart that shows a method of manufacturing a graphene device according to an example embodiment.

FIGS. 5A-5D illustrates a process of a method of manufacturing a molecule layer pattern according to an example embodiment.

FIG. 6 is a flowchart that shows a method of manufacturing a molecule layer pattern according to an example embodiment.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here. It will be readily understood that the components of the present disclosure, as generally described herein, and illustrated in the Figures, may be arranged, substituted, combined, and designed in a wide variety of different configurations, all of which are explicitly contemplated and make part of this disclosure.

In addition, unless explicitly described to the contrary, the word “comprise” and variations such as “comprises” or “comprising” will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present.

The term “nanostructure” used hereinafter recites a structure of nanoscale, and includes a nanoribbon, a nanowire, a nanotube, and a structure made of a combination thereof. In addition, nanostructure, as used hereinafter, includes various other shapes.

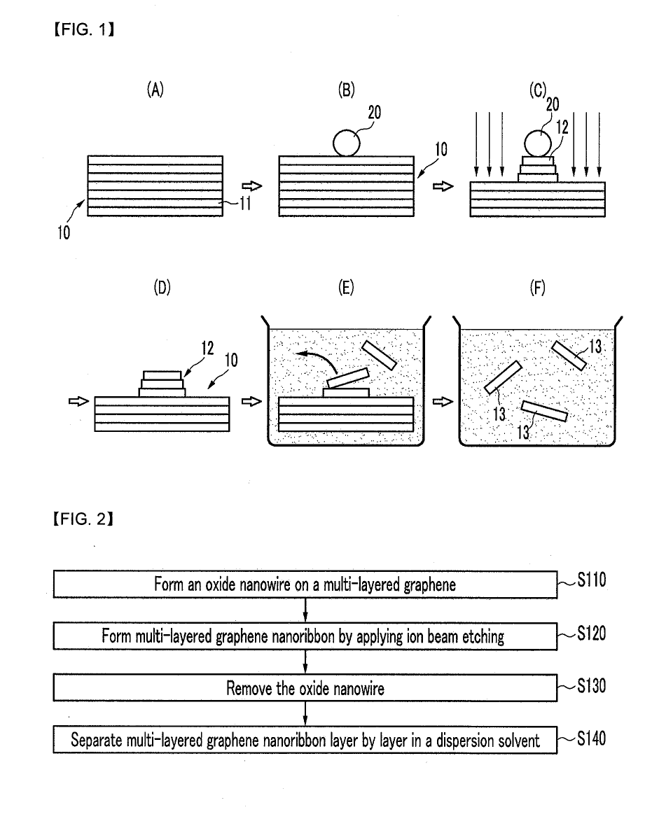

Hereinafter, a method of manufacturing a solution including graphene nanostructures dispersed therein according to an example embodiment is described in detail with reference to FIG. 1 and FIG. 2. A graphene nanoribbon is taken as an example of a graphene nanostructure in the following description, however, it should be understood that other nanostructures are also applicable.

As shown in FIGS. 1(A) and 1(B), an oxide nanowire 20 having a diameter of several nanometers is adhered on a multi-layered graphene 10 utilizing a van der Waals force (S110 in FIG. 2). In the present example embodiment, highly oriented pyrolytic graphite (HOPG) that is currently commercially available is used as the multi-layered graphene 10 that includes a plurality of graphene layers 11.

In the present example embodiment, a van der Waals force is utilized to attach the oxide nanowire 20 to the graphene 10. However, it is notable that the oxide nanowire 20 may be adhered to the graphene 10 in various other ways, for example by utilizing an electrostatic force. A vanadium oxide nanowire, by way of example, may be used as the oxide nanowire 20, and in the following description, the oxide nanowire 20 is referred to as a vanadium oxide nanowire 20 for better understanding of the description.

When the electrostatic force is utilized, a separate voltage is applied to the graphene. When the van der Waals force is utilized, the graphene may simply be dipped in a nanowire solution without the need to apply an external force, and therefore an oxide nanowire may be easily adhered to the graphene.

An oxide nanowire having a covalent bond shows stronger bonding than graphene having a metallic bond, and shows a far lower etch-rate with respect to ion beam milling than graphene. Therefore, an oxide nanowire may be used as a mask in order to remove graphene at the periphery of the mask when an etching period is appropriately controlled.

That is, as shown in FIG. 1(C), when ion beam etching is performed on the multi-layered graphene 10 on which the oxide nanowire 20 is adhered, the graphene under the oxide nanowire 20 remains but the graphene on the other regions is removed since the oxide nanowire 20 acts as a mask, so that a multi-layered graphene nanoribbon 12 having a width of several nanometers is formed (S120 in FIG. 2). In FIG. 1, a multi-layered graphene before the etching is marked by the reference numeral 10, and a graphene nanoribbon formed after the etching is marked by the reference numeral 12.

In the present example embodiment, a vanadium oxide nanowire is taken as an example of the oxide nanowire 20 used as a mask since the vanadium oxide nanowire may be easily formed in a very narrow nanoscale size.

Other than the vanadium oxide, any material that has strong resistivity with respect to an ion beam may be used. As an example, oxide materials such as, by way of example, vanadium pentoxide (V₂O₅) (other vanadium oxides VxOy may also be used), zinc oxide (ZnO₅), and silicon dioxide (SiO₂) typically show high resistivity with respect to an ion beam. This is partly because the bonding strength thereof is high. Additionally, since the oxides are typically insulators, charges generated when exposed to the ion beam do not flow but are accumulated, and the accumulated charges may redirect the ion beam. Materials other than the oxide nanowires 20, such as, by way of example, undoped silicon (Si) and germanium (Ge), may also be used since they show high resistivity with respect to an ion beam.

In FIG. 1(C), anisotropic etching using an ion beam etching is performed using the oxide nanowire 20 as a mask, however, anisotropic etching such as etching using oxygen plasma may be employed.

Subsequently, as shown in FIG. 1(D), the oxide nanowire 20 adhered to the graphene 10 is detached from a surface of the graphene 10 by dipping in a nanowire removal solution (S130 in FIG. 2), and the multi-layered graphene nanoribbon 12 is formed. The nanowire removal solution may be selected based on electric affinity of the oxide nanowire 20. In the present example embodiment, the oxide nanowire 20 is separated from the graphene surface by dipping the graphene attached with the oxide nanowire 20 in a sodium chloride (NaCl) solution, so that the multi-layered graphene nanoribbon 12 is produced.

Subsequently, such produced multi-layer graphene nanoribbon 12 is put in a dispersion solvent and ultrasonic waves are applied thereto as shown in FIG. 1(E), so that the multi-layered graphene nanoribbon 12 is separated layer by layer, thus producing a graphene nanostructure solution having graphene nanoribbons 13 dispersed therein as shown in FIG. 1(F) (S140 in FIG. 2).

In the present embodiment, o-dichlorobenzene is used as a dispersion solvent. However, other materials such as, by way of example, 1,2-dichloroethane or poly(m-phenylenevinylene-co-2,5-dioctoxy-p-phenylenevinylene) may also be used.

According to the present example embodiment illustrated in FIG. 1, graphene nanostructures having a uniform width obtained by etching using an oxide nanowire 20 as a mask are dispersed in a solvent, and thereby a solution having nanostructure graphenes of a uniform width dispersed therein may be manufactured.

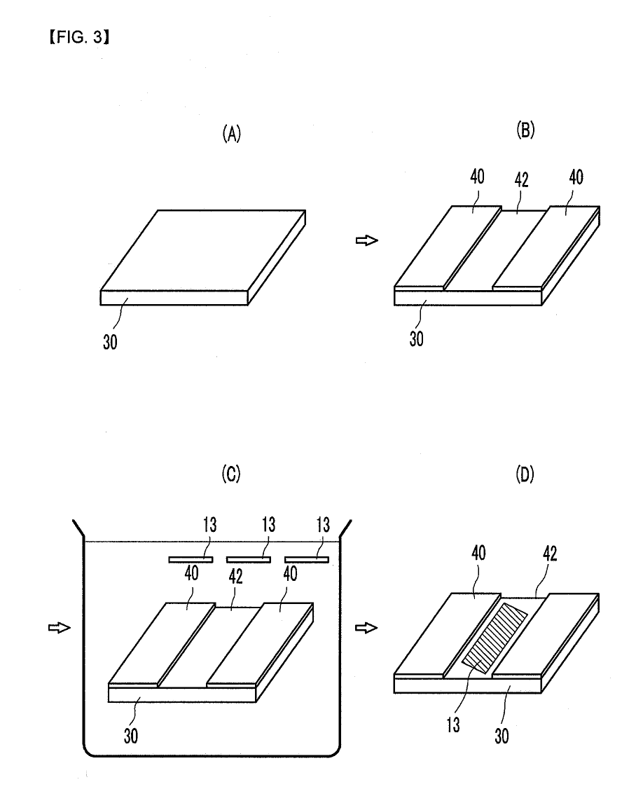

Hereinafter, a method of manufacturing a graphene device using a solution having graphene nanostructures dispersed therein is described in detail with reference to FIG. 3 and FIG. 4. A graphene device described hereinafter is manufactured by using a solution having graphene nanostructures dispersed therein that is produced according to the method illustrated in FIG. 1. However, the graphene device may be produced using a solution having graphene nanostructures dispersed therein that is produced according to other suitable methods to produce the solution with the dispersed graphene nanostructures.

The graphene has a benzene ring and a double bond of carbons, and accordingly has a dipole by a delocalized electron. Therefore, graphenes are not assembled with a hydrophobic molecule layer but are assembled with a hydrophilic molecule layer or a solid surface that is charged with the opposite polarity with respect to the graphenes. A method of manufacturing a nanoscale graphene structure described hereinafter employs a technique for forming a graphene nanoribbon at a specific position and direction on a substrate utilizing the selective assembling characteristic on a hydrophilic molecule layer or a solid surface, which is hereinafter referred to as a “selective assembly process.”

As shown in FIGS. 3(A) and 3(B), a molecule layer pattern 40 is formed on a substrate 30 (S210 in FIG. 4). Silicon (SiO₂), glass, aluminum (Al₂O₃), zirconium (ZrO₂), hafnium (HfO₂), etc. that have an oxide surface may be used as the substrate 30. The molecule layer pattern 40 is a hydrophobic molecule layer pattern and is used for aligning the graphene nanostructures on the substrate, as will be further described in detail below.

While the molecule layer pattern 40 may be formed in various ways, photolithography is used in the present example embodiment, since a molecule layer pattern utilizing photolithography is beneficial for compatibility with a conventional semiconductor process. However, techniques other than photolithography, for example microcontact printing or dip-pen nanolithography (DPN), may also be utilized to form the molecule layer pattern 40.

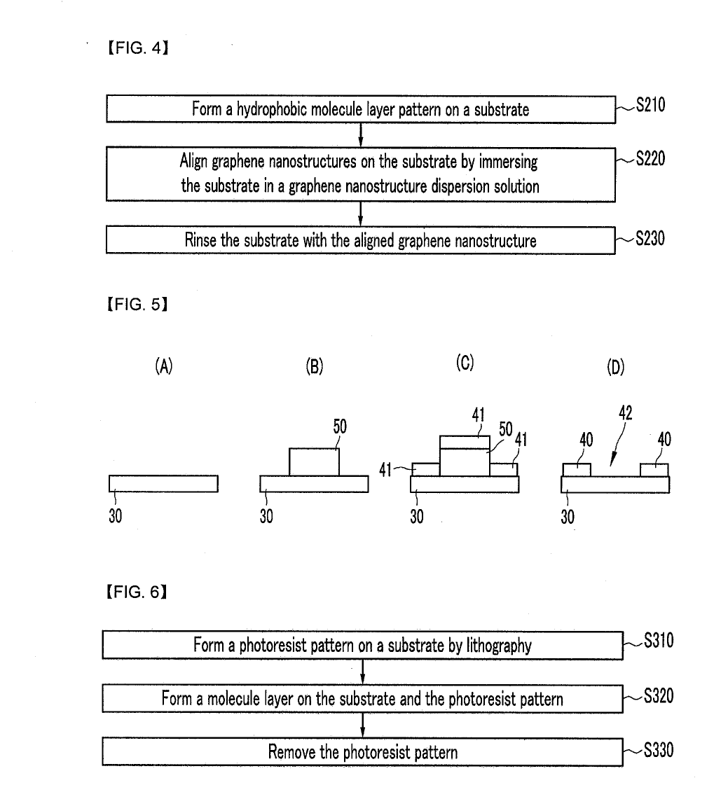

FIG. 5 and FIG. 6 illustrate a method of manufacturing the molecule layer pattern 40 using photolithography. As shown in FIGS. 5(A) and 5(B), a photoresist pattern 50 is first formed on the substrate 30 by photolithography (S310 in FIG. 6). The photoresist pattern 50 is formed on a region 42 of the substrate 30 where the graphene nanostructures will be formed. Subsequently, the substrate with the photoresist pattern 50 is dipped in a solution wherein molecules for forming the molecule layer pattern 40 are dissolved. Then, as shown in FIG. 5(C), the molecules dissolved in the solution adhere to the substrate so that a molecule layer 41 is formed on the substrate 30 and the photoresist pattern 50 (S320 in FIG. 6).

Subsequently, as shown in FIG. 5(D), when the photoresist pattern 50 is removed by acetone (S330 in FIG. 6), the molecule layer 41 on the photoresist pattern 50 may also be removed, so that the molecule layer pattern 40 formed on the substrate 30 and the region 42 may be exposed. Any solvent that does not substantially dissolve the photoresist may be used as the solvent containing the molecules for the molecule layer pattern 40. In the present example embodiment, an AZ5214 resist is used for the photoresist pattern 50, however, another photoresist may also be used.

At this time, molecules such as, by way of example, octadecyltrichlorosilane (OTS), octadecyltrimethoxysilane (OTMS), and octadecyl-triethoxysilane (OTE) that are hydrophobic molecules may be used for the molecule layer pattern 40 used for aligning the graphene on the substrate. The molecule layer pattern 40 shown in FIG. 3 is formed of only hydrophobic molecules, and the molecule layer pattern 40 formed of only hydrophobic molecules is hereinafter referred to as hydrophobic molecule layer pattern 40.

Subsequently, referring back to FIG. 3 and FIG, 4, the substrate applied with the hydrophobic molecule layer pattern 40 is immersed in the graphene nanostructure dispersion solution as shown in FIG. 3(C) (S220 in FIG. 4). Then, graphene nanostructures 13 dispersed in the solution adhere to and align in the solid surface region 42 that is not covered with the hydrophobic molecule layer pattern 40 (refer to FIG. 3(D)).

Although the graphene nanostructures adhere to the substrate region 42 that is not covered with the hydrophobic molecule layer pattern 40 without any prior treatment according to the present example embodiment illustrated in FIG. 3, it is notable that a hydrophilic molecule layer may be previously formed to the region where the graphene nanostructures are to be adhered. At this time, a new type of molecule layer pattern including the hydrophobic molecule layer and the hydrophilic molecule layer is formed on the substrate 30.

A hydrophilic molecule layer may help adhesion of the graphene nanostructure to the substrate by increasing affinity therebetween. In further detail, graphene nanostructures may be adhered to the hydrophilic molecule layer by applying a positive voltage to the substrate after forming the hydrophilic molecule layer in the region where the graphene is adhered.

Aminopropyltriethoxysilane (APTES), 3-mercaptopropyl trimethoxysilane (MPTMS), etc., may be used for the hydrophilic molecule layer.

Finally, the substrate with the graphene nanostructures as shown in FIG. 3(D) is rinsed so that undesired graphene nanostructures that may possibly stay on the hydrophobic molecule layer pattern 40 without adhering thereto can be removed.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A method of manufacturing a graphene nanostructure solution, comprising:
forming a target nanostructure on a multi-layered graphene;
forming a multi-layered graphene nanostructure by performing anisotropic etching using the target nanostructure as a mask; and
forming a solution having graphene nanostructures dispersed therein by dispersing the multi-layered graphene nanostructure in a dispersion solvent.

2. The method of claim 1, wherein the target nanostructure is an oxide nanostructure.

3. The method of claim 2, wherein the oxide nanostructure is adhered on the multi-layered graphene nanostructure by a van der Waals force.

4. The method of claim 2, wherein the oxide nanostructure is a vanadium oxide nanowire.

5. The method of claim 1, wherein the dispersion solvent is o-dichlorobenzene.

6. The method of claim 1, wherein the dispersion solvent is 1,2-dichloroethane.

7. The method of claim 1, wherein the dispersion solvent is poly(m-phenylenevinylene-co-2,5-dioctoxy-p-phenylenevinylene).

8. The method of claim 1, wherein the anisotropic etching is ion beam etching using the target nanostructure as a mask.

9. A method of manufacturing a graphene nano device, comprising:
forming a molecule layer pattern having a hydrophobic molecule layer in a first region on a substrate; and
aligning a graphene nanostructure in a second region of the substrate where the hydrophobic molecule layer is not formed.

10. The method of claim 9, wherein the molecule layer pattern is formed by utilizing a photolithography process.

11. The method of claim 9, wherein a hydrophilic molecule layer is formed in the second region of the substrate.

12. The method of claim 9, wherein the graphene nanostructure is aligned in the second region of the substrate by dipping the substrate with the molecule layer pattern in a solution having graphene nanostructures dispersed therein.

13. A method of manufacturing a graphene nano device, comprising:
forming a target nanostructure on a multi-layered graphene;
forming a multi-layered graphene nanostructure by performing anisotropic etching using the target nanostructure as a mask;
forming a solution having graphene nanostructures dispersed therein by dispersing the multi-layered graphene nanostructure in a dispersion solvent;
forming a molecule layer pattern having a hydrophobic molecule layer in a first region on a substrate; and
aligning a graphene nanostructure in a second region of the substrate where the hydrophobic molecule layer is not formed, by dipping the substrate with the molecule layer pattern in a solution having graphene nanostructures dispersed therein.

14. The method of claim 13, wherein the oxide nanostructure is adhered on the multi-layered graphene nanostructure by a van der Waals force.

15. The method of claim 13, wherein the oxide nanostructure is a vanadium oxide nanowire.

16. The method of claim 13, wherein the molecule layer pattern is formed by utilizing a photolithography process.

17. The method of claim 13, wherein a hydrophilic molecule layer is formed in the second region of the substrate.

18. The method of claim 13, wherein the anisotropic etching is ion beam etching using the target nanostructure as a mask.
